(19) United States
(12) Patent Application Publication
(10) Pub. No.: US 2025/0380351 A1
(43) Pub. Date: Dec. 11, 2025

(54) SEMICONDUCTOR DEVICE AND METHOD FOR MANUFACTURING SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Yuzeng LIU, Osaka (JP); Yuichi FUJITA, Hyogo (JP)

(73) Assignees: Kabushiki Kaisha Toshiba, Kawasaki-shi (JP); Toshiba Electronic Devices & Storage Corporation, Kawasaki-shi (JP)

(21) Appl. No.: 19/313,058

(22) Filed: Aug. 28, 2025

Related U.S. Application Data
(63) Continuation of application No. PCT/JP2024/006035, filed on Feb. 20, 2024.

(30) Foreign Application Priority Data
Sep. 20, 2023 (JP) 2023-152072

(51) Int. Cl. H05K 1/02; H01L 23/00; H01L 23/053; H01L 23/31; H01L 25/07; H05K 3/12; H10D 80/00; H10D 80/20

(52) U.S. Cl. CPC H05K 1/0203; H01L 23/053; H01L 25/072; H05K 3/1283; H01L 23/3121; H01L 24/48; H01L 2224/48225; H05K 2201/032; H05K 2201/06; H05K 2201/09209; H05K 2201/10166; H10D 80/00; H10D 80/251

(57) ABSTRACT

A semiconductor device according to an embodiment has a circuit board having a first surface facing a first side, and a second surface facing a second side on a side opposite to the first side. The semiconductor device has a chip mounted on the first surface. The semiconductor device has a heat transfer member joined to the second surface with a first joint layer therebetween. The semiconductor device has a heat dissipation member joined to a surface of the heat transfer member facing the second side with a second joint layer therebetween. Each of the first joint layer and the second joint layer is a sintered body.

### CROSS-REFERENCE TO RELATED APPLICATION

This application is based upon and claims the benefit of priority from Japanese Patent Application No. 2023-152072, filed Sep. 20, 2023, the entire contents of which are incorporated herein by reference.

### FIELD

Embodiments described herein relate generally to a semiconductor device and a method for manufacturing a semiconductor device.

### BACKGROUND

In a semiconductor device, the amount of heat generated in a chip mounted on a substrate is likely to be large. In addition, in the case where a substrate and a heat dissipation member are joined using solder, since voids (gaps) are likely to be formed inside the solder, the thermal resistance between the substrate and the heat dissipation member increases sometimes. In this case, since the amount of heat dissipating from the heat dissipation member decreases due to the decrease in the amount of heat transferred from the chip to the heat dissipation member, there is concern that the temperature of the chip may become excessively high. When the temperature of the chip becomes excessively high, there is concern that operation of the semiconductor device may become unstable.

### BRIEF DESCRIPTION OF THE DRAWINGS

FIG. 1 is a schematic cross-sectional view showing a semiconductor device of a first embodiment.

FIG. 2 is a schematic cross-sectional view showing a part of the semiconductor device of the first embodiment.

FIG. 3 is a flowchart showing a method for manufacturing a semiconductor device of the first embodiment.

FIG. 4 is a first schematic cross-sectional view showing the method for manufacturing a semiconductor device of the first embodiment.

FIG. 5 is a second schematic cross-sectional view showing the method for manufacturing a semiconductor device of the first embodiment.

FIG. 6 is a third schematic cross-sectional view showing the method for manufacturing a semiconductor device of the first embodiment.

FIG. 7 is a schematic cross-sectional view showing a part of a semiconductor device of a second embodiment.

FIG. 8 is a flowchart showing the method for manufacturing a semiconductor device of the second embodiment.

FIG. 9 is a first schematic cross-sectional view showing the method for manufacturing a semiconductor device of the second embodiment.

FIG. 10 is a second schematic cross-sectional view showing the method for manufacturing a semiconductor device of the second embodiment.

FIG. 11 is a schematic cross-sectional view showing a part of a semiconductor device of a third embodiment.

FIG. 12 is a schematic cross-sectional view showing a part of a semiconductor device of a fourth embodiment.

FIG. 13 is a view of a part of the semiconductor device of the fourth embodiment viewed from a first side.

### DETAILED DESCRIPTION

A semiconductor device according to an embodiment has a circuit board having a first surface facing a first side, and a second surface facing a second side on a side opposite to the first side. The semiconductor device has a chip mounted on the first surface. The semiconductor device has a heat transfer member joined to the second surface with a first joint layer therebetween. The semiconductor device has a heat dissipation member joined to a surface of the heat transfer member facing the second side with a second joint layer therebetween. Each of the first joint layer and the second joint layer is a sintered body.

Hereinafter, the semiconductor device according to embodiments will be described with reference to the drawings.

A Z axis direction shown in each of the drawings is a vertical direction. A side to which the arrow in the Z axis direction points (positive Z side) is an upward side in the vertical direction. A side opposite to the side to which the arrow in the Z axis direction points (negative Z side) is a downward side in the vertical direction. In the following description, the upward side in the vertical direction will be simply referred to as “upward side” or “first side”, and the downward side in the vertical direction will be simply referred to as “downward side” or “second side”. The second side is a side opposite to the first side. Each of “upward side” and “downward side” is not a term indicating a relationship with the direction of gravity. In addition, in the following description, a surface, of outer surfaces of each member, each layer, and the like constituting the semiconductor device, facing the first side will be referred to as a front surface, and a surface thereof facing the second side will be referred to as a rear surface.

### First Embodiment

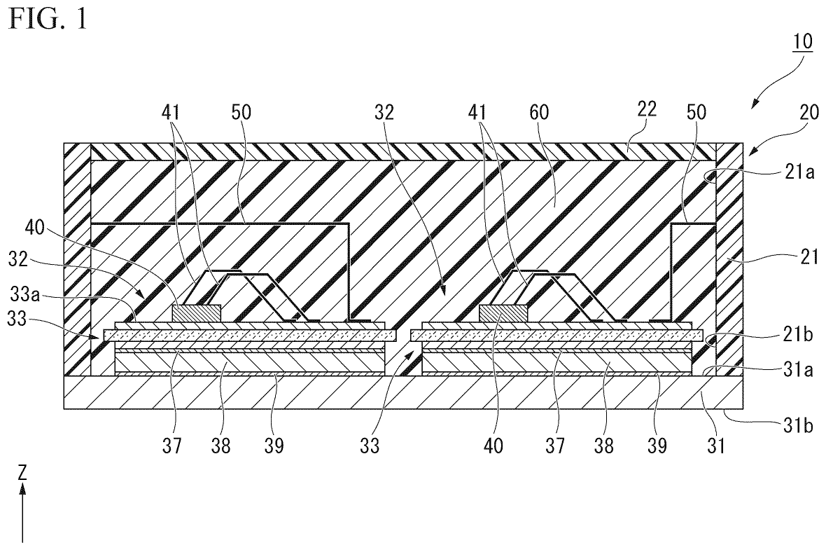

FIG. 1 is a schematic cross-sectional view of a semiconductor device 10 of the present embodiment. For example, the semiconductor device 10 of the present embodiment is a power semiconductor device, such as a metal oxide semiconductor field effect transistor (MOSFET) or an insulated gate bipolar transistor (IGBT). The semiconductor device 10 includes a case 20, a heat dissipation member 31, a main body portion 32, a terminal portion 50, and a sealing material 60. The semiconductor device does not have to include the case 20.

The case 20 accommodates the main body portion 32, the terminal portion 50, and the sealing material 60 therein. In the present embodiment, the case 20 is made of a resin. The case 20 has a circumferential wall portion 21 and a lid member 22.

The circumferential wall portion 21 surrounds the main body portion 32, the terminal portion 50, and the sealing material 60. The circumferential wall portion 21 has a tubular shape extending in the vertical direction. In the present embodiment, the circumferential wall portion 21 has a rectangular tube shape. The circumferential wall portion 21 may have other shapes such as a cylindrical shape or a hexagonal tube shape. The circumferential wall portion 21 has a first opening 21a opening to the upward side, and a second opening 21b opening to the downward side.

The lid member 22 has a plate shape extending in a direction orthogonal to the vertical direction. In the present embodiment, when viewed in the vertical direction, the lid member 22 has substantially a rectangular shape. The lid member 22 is fixed to an upper end of the circumferential wall portion 21. The lid member 22 blocks the first opening 21a.

The heat dissipation member 31 has a plate shape extending in a direction orthogonal to the vertical direction. The heat dissipation member 31 is fixed to a lower end of the circumferential wall portion 21. The heat dissipation member 31 blocks the second opening 21b of the circumferential wall portion 21. The main body portion 32 is joined to a front surface 31a of the heat dissipation member 31. A rear surface 31b of the heat dissipation member 31 is exposed to the outside of the semiconductor device 10.

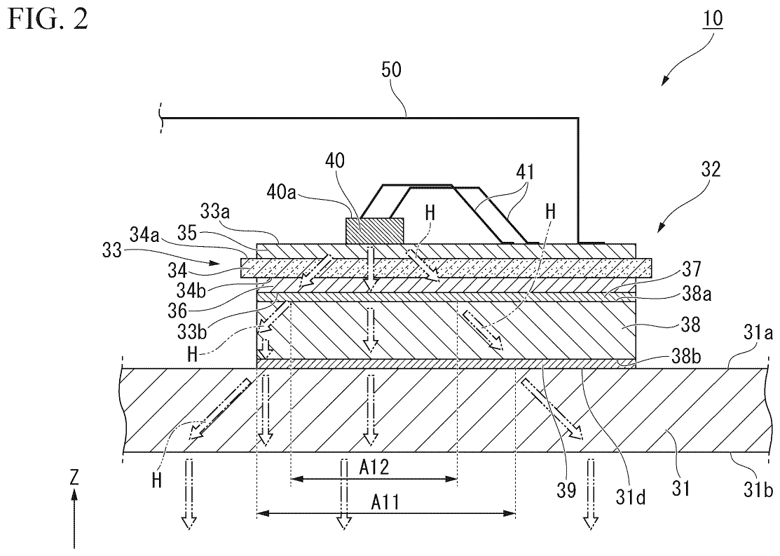

In the present embodiment, the heat dissipation member 31 is made of a metal. For example, the heat dissipation member 31 is constituted using a metal such as copper, aluminum, nickel, silver, or gold. In the present embodiment, the heat dissipation member 31 is made of copper. As shown in FIG. 2, an outer surface of the heat dissipation member 31 is covered by a nickel protective film 31d. In the present embodiment, the protective film 31d is formed by plating. The heat dissipation member 31 may be constituted using other materials such as a metal matrix composite material obtained by dispersing particles of silicon carbide in an aluminum alloy. The heat dissipation member 31 may be a heat sink.

The main body portion 32 is an inverter generating a high-frequency alternating current from a direct current supplied from an external power source (not shown). The main body portion 32 may be a converter. As shown in FIG. 1, the main body portion 32 is accommodated inside the case 20. In the present embodiment, the semiconductor device 10 has a plurality of main body portions 32. As shown in FIG. 2, each main body portion 32 includes a circuit board 33, a first joint layer 37, a heat transfer member 38, a second joint layer 39, a chip 40, and wires 41.

The circuit board 33 extends in a direction orthogonal to the vertical direction. The circuit board 33 is accommodated inside the case 20. The circuit board 33 has a first surface 33a and a second surface 33b. The first surface 33a is a surface, of outer side surfaces of the circuit board 33, facing the first side (positive Z side). The first surface 33a is a front surface of the circuit board 33. The second surface 33b is a surface, of the outer side surfaces of the circuit board 33, facing the second side (negative Z side). The second surface 33b is a rear surface of the circuit board 33. The circuit board 33 has an insulating substrate 34, a circuit portion 35, and a conductor portion 36. The insulating substrate 34 has a plate shape extending in a direction orthogonal to the vertical direction. The insulating substrate 34 has insulating properties. The insulating substrate 34 is a ceramic substrate. For example, the insulating substrate 34 is constituted using ceramic such as silicon nitride or aluminum nitride.

The circuit portion 35 is provided on a front surface 34a of the insulating substrate 34. The circuit portion 35 is made of a metal. In the present embodiment, the circuit portion 35 is made of copper. The circuit portion 35 may be constituted using other metals such as silver or gold. A circuit pattern (not shown) is formed in the circuit portion 35. A front surface of the circuit portion 35 is the first surface 33a. In a direction orthogonal to the vertical direction, the dimension of the circuit portion 35 is smaller than the dimension of the insulating substrate 34.

The conductor portion 36 is provided on a rear surface 34b of the insulating substrate 34, that is, a surface facing the second side (negative Z side). The conductor portion 36 is made of a metal. In the present embodiment, the conductor portion 36 is made of copper. The conductor portion 36 may be constituted using other metals such as silver or gold. A rear surface of the conductor portion 36 is the second surface 33b. In a direction orthogonal to the vertical direction, the dimension of the conductor portion 36 is smaller than the dimension of the insulating substrate 34. In a direction orthogonal to the vertical direction, the dimension of the conductor portion 36 is a dimension substantially the same as the dimension of the circuit portion 35. In addition, an outer edge portion of the insulating substrate 34 is positioned on an outward side of an outer edge portion of the circuit portion 35 and an outer edge portion of the conductor portion 36. In the present embodiment, since the creepage distance between the circuit portion 35 and the conductor portion 36 can be increased by the insulating substrate 34, the circuit portion 35 and the conductor portion 36 can be insulated from each other. In a direction orthogonal to the vertical direction, the dimension of the conductor portion 36 may be smaller or larger than the dimension of the circuit portion 35.

In the present embodiment, the thickness of the conductor portion 36 is a thickness substantially the same as the thickness of the circuit portion 35. Accordingly, even if the temperature of the circuit board 33 rises due to heat generated in the chip 40, the difference between the amount of thermal expansion of the conductor portion 36 and the amount of thermal expansion of the circuit portion 35 can be reduced. Therefore, since increase in stress applied to the insulating substrate 34 can be curbed due to the difference between the amount of thermal expansion of the conductor portion 36 and the amount of thermal expansion of the circuit portion 35, damage to the insulating substrate 34 can be curbed.

The heat transfer member 38 transfers heat generated in the chip 40 to the heat dissipation member 31. The heat transfer member 38 has a plate shape extending in a direction orthogonal to the vertical direction. The heat transfer member 38 is accommodated inside the case 20. The heat transfer member 38 is disposed on the downward side of the circuit board 33. The heat transfer member 38 is joined to the second surface 33b of the circuit board 33 with the first joint layer 37 therebetween. The heat transfer member 38 is joined to the conductor portion 36 with the first joint layer 37 therebetween. The heat transfer member 38 is made of a metal. In the present embodiment, the heat transfer member 38 is made of copper. The heat transfer member 38 may be constituted using other metals such as silver or gold.

The thickness of the heat transfer member 38 is larger than the thickness of the conductor portion 36. In the present embodiment, the thickness of the heat transfer member 38 is larger than the thickness of the circuit board 33. The thickness of the heat transfer member 38 may be the same thickness as the thickness of the circuit board 33 or may be smaller than the thickness of the circuit board 33. In the present embodiment, when viewed from the first side (positive Z side), an outer edge of the heat transfer member 38 overlaps an outer edge of the conductor portion 36. When viewed from the first side, the outer edge of the heat transfer member 38 may surround the outer edge of the conductor portion 36.

The first joint layer 37 joins the circuit board 33 and the heat transfer member 38 to each other. More specifically, the first joint layer 37 joins the conductor portion 36 and the heat transfer member 38 to each other. In the present embodiment, the first joint layer 37 is a copper sintered body. The first joint layer 37 may be a sintered body made of other metals such as silver, or other materials such as ceramic. The first joint layer 37 is a copper film formed by applying a copper paste obtained by dispersing copper particles in a solvent to at least one of the heat transfer member 38 and the conductor portion 36, and firing the copper paste in a state of being in contact with both the heat transfer member 38 and the conductor portion 36. The method for applying the copper paste is not particularly limited, and it can be applied by known screen printing and inkjet printing. In addition, a copper paste which has been formed to have a sheet shape in advance may be used. Since the first joint layer 37 is a sintered body, compared to the case where the first joint layer 37 is constituted using solder, for example, formation of voids inside the first joint layer 37 can be curbed. The thickness of the first joint layer 37 is smaller than the thickness of the conductor portion 36 and the thickness of the heat transfer member 38. From the viewpoint of joining strength between the circuit board 33 and the heat transfer member 38, the thickness of the first joint layer 37 is preferably 10 μm or larger. In addition, from the viewpoint of work time required for firing the first joint layer 37, the thickness of the first joint layer 37 is preferably 100 μm or smaller. In the present embodiment, the thickness of the first joint layer 37 is approximately 50 μm.

The second joint layer 39 joins the heat dissipation member 31 and the heat transfer member 38 to each other. The heat dissipation member 31 is joined to a rear surface 38b of the heat transfer member 38, that is, a surface facing the second side (negative Z side) with the second joint layer 39 therebetween. In the present embodiment, the second joint layer 39 is a silver sintered body. The second joint layer 39 may be a sintered body made of other metals such as copper, or other materials such as ceramic. The second joint layer 39 is a silver film formed by applying a silver paste obtained by dispersing silver particles in a solvent to at least one of the heat dissipation member 31 and the heat transfer member 38, and firing the silver paste in a state of being in contact with both the heat dissipation member 31 and the heat transfer member 38. Since the second joint layer 39 is a sintered body, compared to the case where the second joint layer 39 is constituted using solder, for example, formation of voids inside the second joint layer 39 can be curbed. The thickness of the second joint layer 39 is smaller than the thickness of the heat transfer member 38. From the viewpoint of joining strength between the heat dissipation member 31 and the heat transfer member 38, the thickness of the second joint layer 39 is preferably 10 μm or larger. In addition, from the viewpoint of work time required for firing the second joint layer 39, the thickness of the second joint layer 39 is preferably 100 μm or smaller. In the present embodiment, the thickness of the second joint layer 39 is approximately 50 μm. The chip 40 is mounted on the first surface 33a of the circuit board 33. For example, the chip 40 includes a power element for electric power control. In the case where the chip 40 is a MOSFET or a gallium nitride (GaN) device, a drain electrode of the chip 40 is mounted on the circuit board 33 with a mounting material constituted using solder, a sintered material, or the like therebetween. In the case where the chip 40 is an IGBT, a collector electrode of the chip 40 is mounted on the circuit board 33 with a mounting material constituted using solder, a sintered material, or the like therebetween. For example, the chip 40 is constituted using a semiconductor material such as silicon (Si), silicon carbide (SiC), or gallium nitride. The number of chips 40 provided in each main body portion 32 may be one or more. Although it is not shown in the diagrams, in the present embodiment, each main body portion 32 includes a plurality of chips 40. When viewed in the vertical direction, the chip 40 overlaps each of the circuit board 33, the first joint layer 37, the heat transfer member 38, the second joint layer 39, and the heat dissipation member 31. A plurality of electrode portions (not shown) are provided on a front surface 40a of the chip 40.

The wires 41 connect the chip 40 and the circuit portion 35 to each other. For example, the wires 41 are constituted using a metal such as aluminum or copper. In the present embodiment, the wires 41 are made of aluminum. Each main body portion 32 includes a plurality of wires 41. One end of each wire 41 is joined to each of the different electrode portions of the chip 40. More specifically, in the case where the chip is a MOSFET or a gallium nitride device, the one wire 41 is connected to a source electrode, and the other wire 41 is connected to a gate electrode. In addition, in the case where the chip 40 is an IGBT, the one wire 41 is connected to an emitter electrode, and the other wire 41 is connected to the gate electrode. The other end of each wire 41 is joined to the circuit portion 35. According to these, each wire 41 electrically connects the chip 40 and the circuit board 33 to each other.

The terminal portion 50 electrically connects an external power source (not shown) to an object (not shown) and the circuit board 33. The object is a device or the like to which a current generated by the semiconductor device 10 is supplied, such as a drive device, for example. As shown in FIG. 1, one end of the terminal portion 50 is held by the case 20. One end of the terminal portion 50 is joined to an electrode (not shown) of the circumferential wall portion 21. As shown in FIG. 2, the other end of the terminal portion 50 is joined to the circuit portion 35. Accordingly, when a current is supplied from an external power source (not shown) to the circuit board 33, the circuit board 33 generates a predetermined wave-shaped output current and supplies the output current to the object.

As shown in FIG. 1, the sealing material 60 covers the main body portion 32 and the terminal portion 50. The sealing material 60 covers each of the circuit board 33, the chip 40, and the wire 41. The sealing material 60 is constituted using a resin having insulating properties. For example, the sealing material 60 is constituted using a resin mainly containing a silicone resin, an epoxy resin, a phenol resin, or an acrylic resin. In the present embodiment, the sealing material 60 is constituted using a silicone resin. According to the present embodiment, due to the sealing material 60, insulation between the wires 41, insulation between each wire 41 and the terminal portion 50, and insulation between the plurality of electrode portions provided in each chip 40 can be secured. In addition, due to the sealing material 60, the main body portion 32 can be protected.

According to these, operational stability of the semiconductor device 10 can be improved.

Next, a heat transfer path through which heat generated in the chip 40 dissipates to the outside of the semiconductor device 10 via the circuit board 33, the heat transfer member 38, and the heat dissipation member 31 will be described. In FIG. 2, the heat transfer path is schematically indicated by arrows H. Heat generated in the chip 40 is transferred to the downward side while spreading in a direction orthogonal to the vertical direction in the circuit board 33, and is transferred to the heat transfer member 38 via the first joint layer 37. Heat transferred to the heat transfer member 38 is transferred to the downward side while spreading in a direction orthogonal to the vertical direction in the heat transfer member 38, and is transferred to the heat dissipation member 31 via the second joint layer 39. Heat transferred to the heat dissipation member 31 is transferred to the downward side while spreading in a direction orthogonal to the vertical direction in the heat dissipation member 31, and dissipates to the outside of the semiconductor device from the rear surface 31b of the heat dissipation member 31. According to these, heat generated in the chip 40 dissipates to the outside of the semiconductor device 10.

As described above, since heat transferred to the heat transfer member 38 is transferred to the downward side while spreading in a direction orthogonal to the vertical direction in the heat transfer member 38, an area A11 on the front surface 31a of the heat dissipation member 31 in which heat is transferred from the heat transfer member 38 is larger than an area A12 on a front surface 38a of the heat transfer member 38 in which heat is transferred from the circuit board 33. For instance, in a constitution in which the semiconductor device 10 does not include the heat transfer member 38, namely, in a constitution in which the heat dissipation member 31 is joined to the circuit board 33, the area on the front surface 31a of the heat dissipation member 31 in which heat is transferred from the circuit board 33 becomes an area substantially the same as the area A12. Therefore, in the present embodiment, the area A11 in which heat generated in the chip 40 is transferred to the heat dissipation member 31 can be increased by providing the heat transfer member 38 between the circuit board 33 and the heat dissipation member 31.

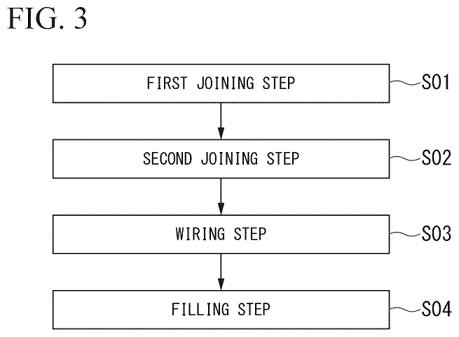

Next, a method for manufacturing the semiconductor device 10 of the present embodiment will be described. As shown in FIG. 3, the method for manufacturing the semiconductor device 10 of the present embodiment has a first joining step S01 of forming the second joint layer 39 by pressure sintering and joining the heat transfer member 38 and the heat dissipation member 31 to each other with the second joint layer 39 therebetween, a second joining step S02 of forming the first joint layer 37 by pressureless sintering and joining the circuit board 33 having the chip 40 mounted thereon and the heat transfer member 38 to each other with the first joint layer 37 therebetween, a wiring step S03 of joining the terminal portion 50 to the circuit board 33, and a filling step S04 of filling the inside of the circumferential wall portion 21 with the sealing material 60. In the following description, “a worker or the like” includes a worker, assembly equipment, or the like performing each step of work. Each step of work may be performed by only a worker, may be performed by only assembly equipment, or may be performed by a worker and assembly equipment.

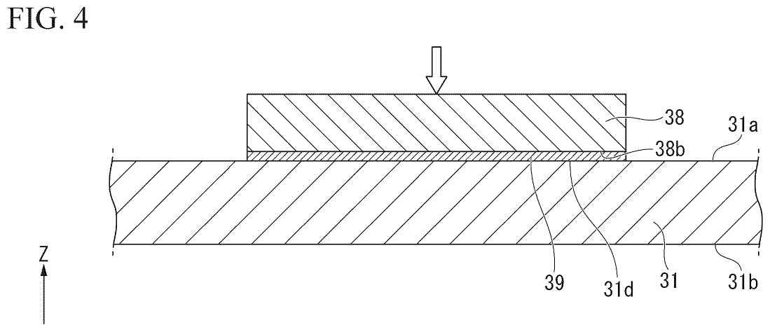

In the first joining step S01, the second joint layer 39 is formed by pressure sintering, and the heat transfer member 38 and the heat dissipation member 31 are joined to each other with the second joint layer 39 therebetween. As shown in FIG. 4, in the first joining step S01, the worker or the like first applies the silver paste described above to at least one of the heat dissipation member 31 and the heat transfer member 38. Next, the worker or the like brings the front surface 31a of the heat dissipation member 31 into contact with the rear surface 38b of the heat transfer member 38 with the silver paste therebetween. Next, the worker or the like performs pressure sintering to sinter the silver paste while pressurizing the silver paste by pressurizing the heat transfer member 38 from the upward side. When silver particles contained in the silver paste are bonded to each other and the second joint layer 39 (silver sintered body) is formed, the heat transfer member 38 and the heat dissipation member 31 are joined to each other with the second joint layer 39 therebetween. When the second joint layer 39 is formed, the first joining step S01 ends.

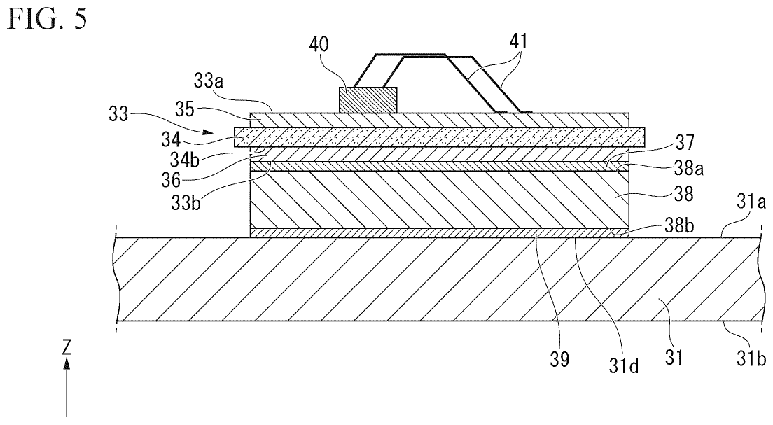

In the second joining step S02, the first joint layer 37 is formed by pressureless sintering, and the circuit board 33 having the chip 40 mounted thereon and the heat transfer member 38 are joined to each other with the first joint layer 37 therebetween. As shown in FIG. 5, in the second joining step S02, the worker or the like first applies the copper paste described above to at least one of the heat transfer member 38 and the conductor portion 36. In the present embodiment, in the step before the second joining step S02, each of the circuit portion 35 and the conductor portion 36 is provided in the insulating substrate 34. Moreover, in the step before the second joining step S02, the chip 40 is mounted on the first surface 33a, and the wire 41 is joined to each of the chip and the circuit portion 35. Next, the worker or the like brings the front surface 38a of the heat transfer member 38 into contact with the rear surface of the conductor portion 36, that is, the second surface 33b of the circuit board 33 with the copper paste therebetween. Next, the worker or the like performs pressureless sintering to sinter the copper paste without pressurizing the copper paste. When copper particles contained in the copper paste are bonded to each other and the first joint layer 37 (copper sintered body) is formed, the circuit board 33 and the heat transfer member 38 are joined to each other with the first joint layer 37 therebetween. More specifically, the conductor portion 36 and the heat transfer member 38 are joined to each other with the first joint layer 37 therebetween. When the first joint layer 37 is formed, the second joining step S02 ends.

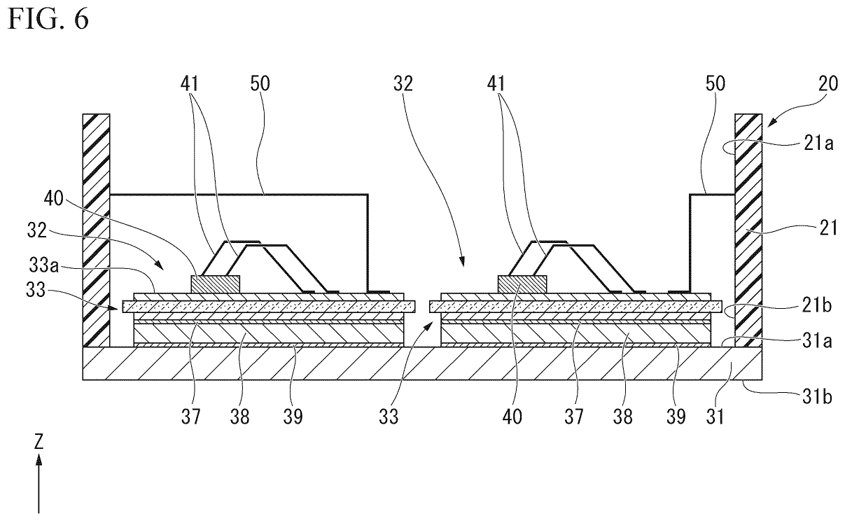

In the wiring step S03, the terminal portion 50 is joined to the circuit board 33. As shown in FIG. 6, in the wiring step S03, the worker or the like first moves the heat dissipation member 31 to which each main body portion 32 is joined from the downward side to the upward side of the circumferential wall portion 21 and inserts each main body portion 32 into the circumferential wall portion 21 through the second opening 21b. Next, the worker or the like fixes the heat dissipation member 31 to the lower end of the circumferential wall portion 21. Next, the worker or the like joins one end of the terminal portion 50 to the electrode (not shown) of the circumferential wall portion 21 and joins the other end of the terminal portion 50 to the circuit portion 35. When the terminal portion 50 is joined to the circuit board 33, the wiring step S03 ends.

In the filling step S04, the inside of the circumferential wall portion 21 is filled with the sealing material 60. In the filling step S04, the worker or the like first fills the inside of the circumferential wall portion 21 with the sealing material 60 using a filling device (not shown). The filling device fills the inside of the circumferential wall portion 21 with the gel-like sealing material 60. Next, as shown in FIG. 1, when the worker or the like fills the inside of the circumferential wall portion 21 with the gel-like sealing material 60 until the main body portion 32 and the terminal portion 50 are covered, the filling of the gel-like sealing material 60 ends. Next, the worker or the like fixes the lid member 22 to the upper end of the circumferential wall portion 21. Next, the worker or the like hardens the gel-like sealing material 60. When the sealing material 60 hardens, the filling step S04 ends. When the filling step S04 ends, the semiconductor device 10 shown in FIG. 1 is manufactured. In the filling step S04, the lid member 22 may be fixed to the upper end of the circumferential wall portion 21 after the gel-like sealing material 60 hardens.

According to the present embodiment, the semiconductor device 10 includes the circuit board 33 having the first surface 33a facing the first side (positive Z side) and the second surface 33b facing the second side (negative Z side) on a side opposite to the first side, the chip 40 mounted on the first surface 33a, the heat transfer member 38 joined to the second surface 33b with the first joint layer 37 therebetween, and the heat dissipation member 31 joined to the rear surface 38b of the heat transfer member 38, that is, the surface facing the second side with the second joint layer 39 therebetween. Each of the first joint layer 37 and the second joint layer 39 is a sintered body. Thus, since the circuit board 33 is joined to the heat dissipation member 31 with the heat transfer member 38 therebetween, as described above, the area A11 in which heat generated in the chip 40 is transferred to the heat dissipation member 31 can be increased. Accordingly, since the amount of heat transferred from the chip 40 to the heat dissipation member 31 can be increased, the amount of heat dissipating to the outside of the semiconductor device 10 from the heat dissipation member 31 can be increased.

Therefore, an excessive rise in the temperature of the chip 40 can be curbed. Thus, operational stability of the semiconductor device 10 can be improved.

In the case where the first joint layer 37 and the second joint layer 39 are constituted using solder, since the solder which has melted at the time of joining is likely to entrap air, voids are likely to be formed inside the first joint layer 37 and the second joint layer 39. In addition, when the semiconductor device 10 is in operation, the temperature of each of the first joint layer 37 and the second joint layer 39 rises and falls repeatedly due to heat generated in the chip 40. In the case where the first joint layer 37 and the second joint layer 39 are constituted using solder, since the solder is likely to be embrittled due to repetition of thermal expansion and thermal contraction, voids are likely to be formed inside the first joint layer 37 and the second joint layer 39. According to these, in the case where the first joint layer 37 and the second joint layer 39 are constituted using solder, the thermal resistance of the first joint layer 37 and the thermal resistance of the second joint layer 39 are likely to increase. In contrast, in the present embodiment, since each of the first joint layer 37 and the second joint layer 39 is a sintered body, the first joining step S01 and in the second joining step S02, formation of voids inside the first joint layer 37 and the second joint layer 39 can be curbed. In addition, since the strength of the first joint layer 37 and the strength of the second joint layer 39 are higher than the strength of the solder, even if thermal expansion and thermal contraction are repeated, formation of voids inside the first joint layer 37 and the second joint layer 39 can be curbed. According to these, since increase in the thermal resistance of the first joint layer 37 and the thermal resistance of the second joint layer 39 can be curbed, decrease in the amount of heat transferred from the chip 40 to the heat dissipation member 31 can be curbed. Therefore, since an excessive rise in the temperature of the chip 40 can be further curbed, operational stability of the semiconductor device 10 can be further improved.

According to the present embodiment, the outer surface of the heat dissipation member 31 is covered by the nickel protective film 31d, and the second joint layer 39 is a silver sintered body. Thus, compared to the case where the second joint layer 39 is a copper sintered body, the joining strength between the second joint layer 39 and the protective film 31d can be enhanced. Accordingly, since increase in the thermal resistance between the second joint layer 39 and the heat dissipation member 31 can be curbed, the amount of heat transferred from the chip 40 to the heat dissipation member 31 can be increased. Therefore, since an excessive rise in the temperature of the chip 40 can be more favorably curbed, operational stability of the semiconductor device 10 can be more favorably improved.

According to the present embodiment, the heat transfer member 38 is made of copper, and the first joint layer 37 is a copper sintered body. Thus, since the heat transfer member 38 and the first joint layer 37 are constituted using the same material, the joining strength between the heat transfer member 38 and the first joint layer 37 can be enhanced. Accordingly, since increase in the thermal resistance between the heat transfer member 38 and the first joint layer 37 can be curbed, the amount of heat transferred from the chip 40 to the heat dissipation member 31 can be increased. Therefore, since an excessive rise in the temperature of the chip 40 can be more favorably curbed, operational stability of the semiconductor device 10 can be more favorably improved.

In addition, in the present embodiment, since the heat transfer member 38 and the first joint layer 37 are constituted using the same material as described above, even if the first joint layer 37 is formed by pressureless sintering, decrease in the joining strength between the heat transfer member 38 and the first joint layer 37 can be curbed.

Accordingly, even if the first joint layer 37 is formed by pressureless sintering, increase in the thermal resistance between the heat transfer member 38 and the circuit board 33 can be curbed. Therefore, since decrease in the amount of heat transferred from the chip 40 to the heat dissipation member 31 can be curbed, an excessive rise in the temperature of the chip 40 can be curbed.

According to the present embodiment, the circuit board 33 has the insulating substrate 34 having insulating properties, and the copper conductor portion 36 provided on the rear surface 34b of the insulating substrate 34, that is, a surface facing the second side (negative Z side). The conductor portion 36 and the heat transfer member 38 are joined to each other with the first joint layer 37 therebetween. Thus, since the conductor portion 36 and the first joint layer 37 are constituted using the same material, the joining strength between the conductor portion 36 and the first joint layer 37 can be enhanced. Accordingly, since increase in the thermal resistance between the conductor portion 36 and the first joint layer 37 can be curbed, the amount of heat transferred from the chip 40 to the heat dissipation member 31 can be increased. Therefore, since an excessive rise in the temperature of the chip 40 can be more favorably curbed, operational stability of the semiconductor device 10 can be more favorably improved.

In addition, in the present embodiment, since the conductor portion 36 and the first joint layer 37 are constituted using the same material as described above, even if the first joint layer 37 is formed by pressureless sintering, decrease in the joining strength between the conductor portion 36 and the first joint layer 37 can be curbed. Accordingly, even if the first joint layer 37 is formed by pressureless sintering, increase in the thermal resistance between the heat transfer member 38 and the circuit board 33 can be curbed. Therefore, since decrease in the amount of heat transferred from the chip 40 to the heat dissipation member 31 can be curbed, an excessive rise in the temperature of the chip 40 can be more favorably curbed.

According to the present embodiment, when viewed from the first side (positive Z side), the outer edge of the heat transfer member 38 overlaps the outer edge of the conductor portion 36. Thus, when viewed from the first side, compared to the case where the outer edge of the heat transfer member 38 is disposed on the inward side of the outer edge of the conductor portion 36, it is easier to curb decrease in the area on the front surface 38a of the heat transfer member 38 in which heat is transferred from the conductor portion 36. Accordingly, decrease in the amount of heat transferred from the conductor portion 36 to the heat transfer member 38 can be curbed. Therefore, since decrease in the amount of heat transferred from the chip 40 to the heat dissipation member 31 can be curbed, an excessive rise in the temperature of the chip 40 can be more favorably curbed.

According to the present embodiment, the method for manufacturing the semiconductor device 10 has the first joining step S01 of forming the second joint layer 39 by pressure sintering and joining the heat transfer member 38 and the heat dissipation member 31 to each other with the second joint layer 39 therebetween, and the second joining step S02 of forming the first joint layer 37 by pressureless sintering and joining the circuit board 33 having the chip 40 mounted thereon and the heat transfer member 38 to each other with the first joint layer 37 therebetween. Thus, in the second joining step S02, since the first joint layer 37 is formed by pressureless sintering, the first joint layer 37 can be formed without pressurizing the first surface 33a having the chip 40 mounted thereon to the downward side. Therefore, interference of a tool or the like pressurizing the first surface 33a to the downward side with the first surface 33a having the chip 40 mounted thereon and the wire 41 joined to the first surface 33a can be curbed. For this reason, in the second joining step S02, damage to the chip 40 and the wire 41 can be curbed. Thus, a decrease in the yield of the semiconductor device 10 can be curbed, and operational stability of the semiconductor device 10 can be improved.

In addition, in the present embodiment, as described above, in the first joining step S01, since the second joint layer 39 is formed by pressure sintering, formation of voids inside the second joint layer 39 can be favorably curbed. Accordingly, since increase in the thermal resistance of the second joint layer 39 can be curbed, decrease in the amount of heat transferred from the chip 40 to the heat dissipation member 31 can be curbed. Therefore, since an excessive rise in the temperature of the chip 40 can be curbed, operational stability of the semiconductor device 10 can be improved.

According to the present embodiment, the heat transfer member 38 is made of copper. The circuit board 33 has the insulating substrate 34 having insulating properties, and the copper conductor portion 36 joined to the rear surface 34b of the insulating substrate 34, that is, a surface facing the second side (negative Z side). The first joint layer 37 is a copper sintered body, and the conductor portion 36 and the heat transfer member 38 are joined to each other with the first joint layer 37 therebetween. Thus, since the heat transfer member 38, the conductor portion 36, and the first joint layer 37 are constituted using the same material, even if the first joint layer 37 is formed by pressureless sintering, the joining strength between the first joint layer 37 and each of the heat transfer member 38 and the conductor portion 36 can be enhanced.

Accordingly, even if the first joint layer 37 is formed by pressureless sintering, the adhesion strength between the heat transfer member 38 and the circuit board 33 can be enhanced. Therefore, since the amount of heat transferred from the chip 40 to the heat dissipation member 31 can be increased, an excessive rise in the temperature of the chip can be curbed.

### Second Embodiment

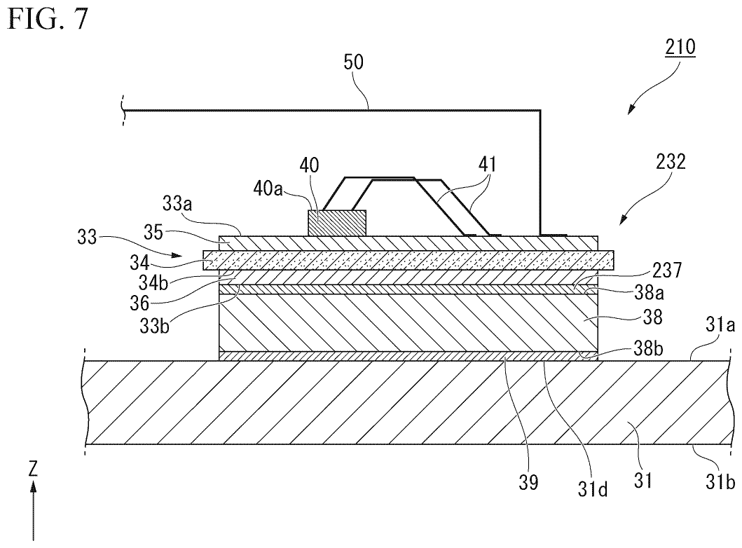

FIG. 7 is a schematic cross-sectional view showing a part of a semiconductor device 210 of the present embodiment. In the semiconductor device 210 of the present embodiment, a first joint layer 237 is formed by pressure sintering. In the following description, the same reference signs are applied to constituent elements having the same form as those of the first embodiment described above, and a description thereof will be omitted.

A main body portion 232 of the present embodiment includes the circuit board 33, the first joint layer 237, the heat transfer member 38, the second joint layer 39, the chip 40, and the wire 41. The first joint layer 237 joins the circuit board 33 and the heat transfer member 38 to each other. More specifically, the first joint layer 237 joins the conductor portion 36 and the heat transfer member 38 to each other. The first joint layer 237 is a copper sintered body. In the present embodiment, the thickness of the first joint layer 237 is approximately 50 μm. Other constitutions and the like of the semiconductor device 210 are the same as other constitutions and the like of the semiconductor device 10 of the first embodiment described above.

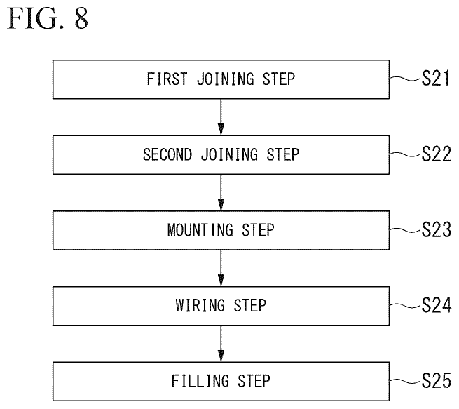

Next, a method for manufacturing the semiconductor device 210 of the present embodiment will be described. As shown in FIG. 8, the method for manufacturing the semiconductor device 210 of the present embodiment has a first joining step S21 of forming the second joint layer 39 by pressure sintering and joining the heat transfer member 38 and the heat dissipation member 31 to each other with the second joint layer 39 therebetween, a second joining step S22 of forming the first joint layer 237 by pressure sintering and joining the circuit board 33 and the heat transfer member 38 to each other with the first joint layer 237 therebetween, a mounting step S23 of mounting the chip 40 on the first surface 33a, a wiring step S24 of joining the terminal portion 50 to the circuit board 33, and a filling step S25 of filling the inside of the circumferential wall portion 21 with the sealing material 60.

In the first joining step S21, the second joint layer 39 is formed by pressure sintering, and the heat transfer member 38 and the heat dissipation member 31 are joined to each other with the second joint layer 39 therebetween. The work and the like in the first joining step S21 are the same as the work and the like in the first joining step S01 of the first embodiment described above.

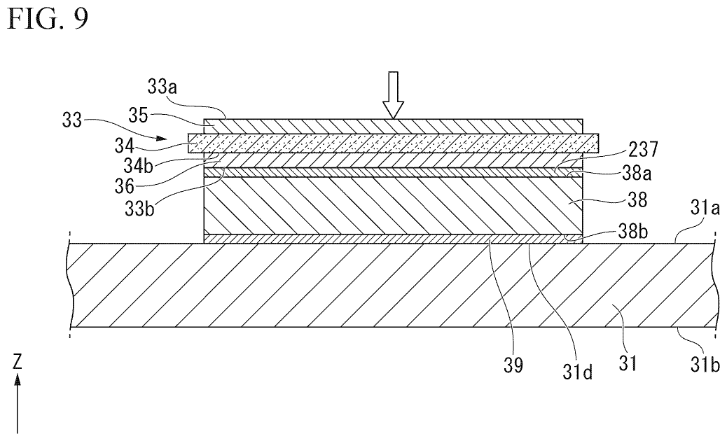

In the second joining step S22, the first joint layer 237 is formed by pressure sintering, and the circuit board 33 and the heat transfer member 38 are joined to each other with the first joint layer 237 therebetween. As shown in FIG. 9, in the second joining step S22, a worker or the like first applies the copper paste described above to at least one of the heat transfer member 38 and the conductor portion 36. In the present embodiment, in the second joining step S22, the chip 40 is not mounted on the first surface 33a of the circuit board 33 and each wire 41 is not joined. Next, the worker or the like brings the front surface 38a of the heat transfer member 38 into contact with the rear surface of the conductor portion 36, that is, the second surface 33b of the circuit board 33 with the copper paste therebetween. Next, the worker or the like performs pressure sintering to sinter the copper paste while pressurizing the copper paste by pressurizing the circuit board 33 from the upward side. When copper particles contained in the copper paste are bonded to each other and the first joint layer 237 (copper sintered body) is formed, the circuit board 33 and the heat transfer member 38 are joined to each other with the first joint layer 237 therebetween. When the first joint layer 237 is formed, the second joining step S22 ends.

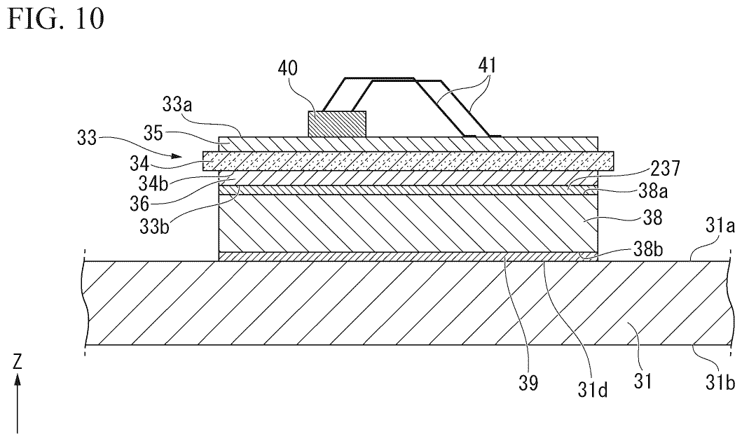

In the mounting step S23, the chip 40 is mounted on the first surface 33a. As shown in FIG. 8, the mounting step S23 is a step performed after the second joining step S22. As shown in FIG. 10, the worker or the like first mounts the chip 40 on the first surface 33a of the circuit board 33. Next, the worker or the like joins one end of the wire 41 to each of the plurality of electrode portions (not shown) provided in the chip 40. Next, the worker or the like joins the other end of each wire 41 to the circuit portion 35. According to these, each wire 41 electrically connects the chip 40 and the circuit board 33 to each other. When each wire 41 is joined to the circuit portion 35, the mounting step S23 ends.

In the wiring step S24, the terminal portion 50 is joined to the circuit board 33. The work and the like in the wiring step S24 are the same as the work and the like in the wiring step S03 of the first embodiment described above. The mounting step S23 may be performed after the wiring step S24. In the filling step S25, the inside of the circumferential wall portion 21 is filled with the sealing material 60. The work and the like in the filling step S25 are the same as the work and the like in the filling step S04 of the first embodiment described above. When the filling step S25 ends, the semiconductor device 210 is manufactured.

According to the present embodiment, the method for manufacturing the semiconductor device 210 has the first joining step S21 of forming the second joint layer 39 by pressure sintering and joining the heat transfer member 38 and the heat dissipation member 31 to each other with the second joint layer 39 therebetween, the second joining step S22 of forming the first joint layer 237 by pressure sintering and joining the circuit board 33 and the heat transfer member 38 to each other with the first joint layer 237 therebetween, and the mounting step S23 of mounting the chip 40 on the first surface 33a after the second joining step S22. Thus, in the second joining step S22, since the chip is not mounted on the first surface 33a, the first surface 33a can be easily pressurized to the downward side. Accordingly, the first joint layer 237 can be formed by pressure sintering. In addition, since the first joint layer 237 is formed by pressure sintering, compared to the case where the first joint layer 237 is formed by pressureless sintering, the contact area between the first joint layer 237 and each of the second surface 33b and the front surface 38a of the heat transfer member 38 can be enhanced. Accordingly, the thermal resistance between the circuit board 33 and the heat transfer member 38 can be reduced. Therefore, since the amount of heat transferred from the chip 40 to the heat dissipation member 31 can be increased, an excessive rise in the temperature of the chip can be more favorably curbed.

In addition, in the present embodiment, since the first joint layer 237 is formed by pressure sintering as described above, compared to the case where the first joint layer 237 is formed by pressureless sintering, formation of voids inside the first joint layer 237 can be curbed. Accordingly, since the thermal resistance of the first joint layer 237 can be reduced, the amount of heat transferred from the chip 40 to the heat dissipation member 31 can be further increased. Therefore, an excessive rise in the temperature of the chip 40 can be more favorably curbed.

### Third Embodiment

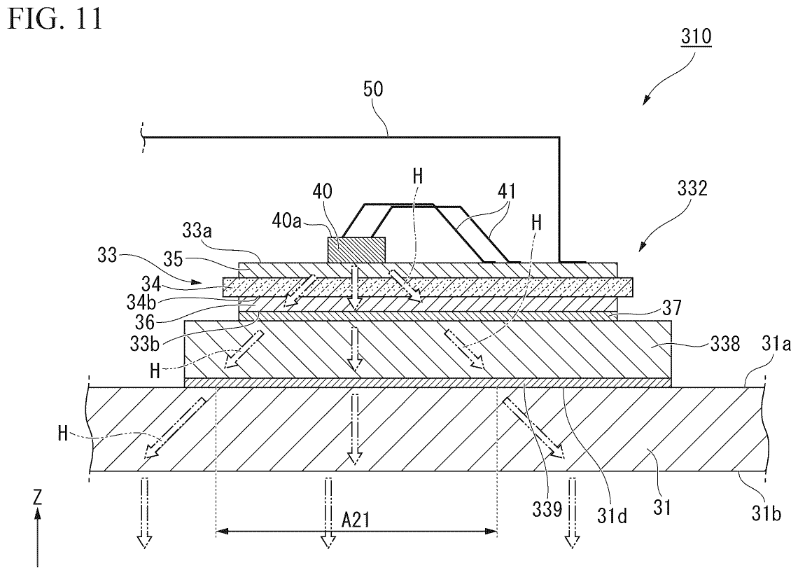

FIG. 11 is a schematic cross-sectional view showing a part of a semiconductor device 310 of the present embodiment. In the semiconductor device 310 of the present embodiment, when viewed from the first side (positive Z side), an outer edge of a heat transfer member 338 surrounds an outer edge of the circuit board 33. In the following description, the same reference signs are applied to constituent elements having the same form as those of the first embodiment described above, and a description thereof will be omitted.

A main body portion 332 of the present embodiment includes the circuit board 33, the first joint layer 37, the heat transfer member 338, a second joint layer 339, the chip 40, and the wire 41. The heat transfer member 338 has a plate shape extending in a direction orthogonal to the vertical direction. The heat transfer member 338 is joined to the second surface 33b of the circuit board 33 with the first joint layer 37 therebetween. The heat transfer member 338 is joined to the conductor portion 36 with the first joint layer 37 therebetween. When viewed from the first side (positive Z side), the outer edge of the heat transfer member 338 surrounds the outer edges of the circuit board 33 and the first joint layer 37. Other constitutions and the like of the heat transfer member 338 are the same as other constitutions and the like of the heat transfer member 38 of the first embodiment described above.

The second joint layer 339 joins the heat transfer member 338 and the heat dissipation member 31 to each other. The second joint layer 339 is a silver sintered body. When viewed from the first side (positive Z side), an outer edge of the second joint layer 339 overlaps the outer edge of the heat transfer member 338. When viewed from the first side, the outer edge of the second joint layer 339 surrounds the outer edge of the circuit board 33. Other constitutions and the like of the second joint layer 339 are the same as other constitutions and the like of the second joint layer 39 of the first embodiment described above. Other constitutions and the like of the semiconductor device 310 are the same as other constitutions and the like of the semiconductor device of the first embodiment described above.

Next, a heat transfer path through which heat generated in the chip 40 dissipates to the outside of the semiconductor device 310 via the circuit board 33, the heat transfer member 338, and the heat dissipation member 31 will be described. In FIG. 11, the heat transfer path is schematically indicated by the arrows H. As described above, heat transferred from the circuit board 33 to the heat transfer member 338 is transferred to the downward side while spreading in a direction orthogonal to the vertical direction in the heat transfer member 338, and is transferred to the heat dissipation member 31 via the second joint layer 339. In the present embodiment, since the outer edge of the heat transfer member 338 surrounds the outer edge of the circuit board 33 as described above, it is easier to increase the area of the heat transfer member 338 in a direction orthogonal to the vertical direction. For this reason, an area A21 on the front surface 31a of the heat dissipation member 31 in which heat is transferred from the heat transfer member 338 can be made larger than the area A11 on the front surface 31a of the heat dissipation member 31 in which heat is transferred from the heat transfer member 38 in the first embodiment shown in FIG. 2. Therefore, in the present embodiment, the area A21 in which heat generated in the chip 40 is transferred to the heat dissipation member 31 can be increased.

According to the present embodiment, when viewed from the first side (positive Z side), the outer edge of the heat transfer member 338 surrounds the outer edge of the circuit board 33. Thus, compared to the constitution in which the outer edge of the heat transfer member 338 overlaps the outer edge of the circuit board 33 or is positioned on the inward side of the outer edge of the circuit board 33 when viewed from the first side, as described above, the area A21 on the front surface 31a of the heat dissipation member 31 in which heat is transferred from the heat transfer member 338 can be increased. Accordingly, the amount of heat transferred from the heat transfer member 338 to the heat dissipation member 31 can be increased. Therefore, since the amount of heat transferred from the chip 40 to the heat dissipation member 31 can be increased, an excessive rise in the temperature of the chip 40 can be more favorably curbed.

### Fourth Embodiment

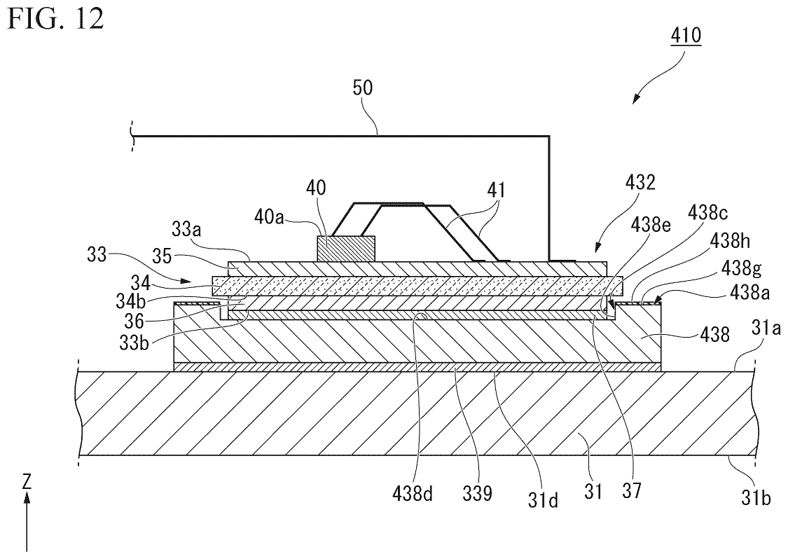

FIG. 12 is a schematic cross-sectional view showing a part of a semiconductor device 410 of the present embodiment. In the semiconductor device 410 of the present embodiment, a recessed portion 438c recessed to the second side (negative Z side) is provided on a front surface 438a of a heat transfer member 438, that is, a surface facing the first side (positive Z side). In the following description, the same reference signs are applied to constituent elements having the same form as those of the third embodiment described above, and a description thereof will be omitted.

A main body portion 432 of the present embodiment includes the circuit board 33, the first joint layer 37, the heat transfer member 438, the second joint layer 339, the chip 40, and the wire 41. The heat transfer member 438 has a plate shape extending in a direction orthogonal to the vertical direction. The heat transfer member 438 is joined to the second surface 33b of the circuit board 33 with the first joint layer 37 therebetween. The heat transfer member 438 is joined to the conductor portion 36 with the first joint layer 37 therebetween. When viewed from the first side (positive Z side), an outer edge of the heat transfer member 438 surrounds the outer edges of the circuit board 33 and the first joint layer 37. The heat transfer member 438 has the recessed portion 438c and a circumferential edge portion 438g. An insulating layer 438h is provided in the heat transfer member 438.

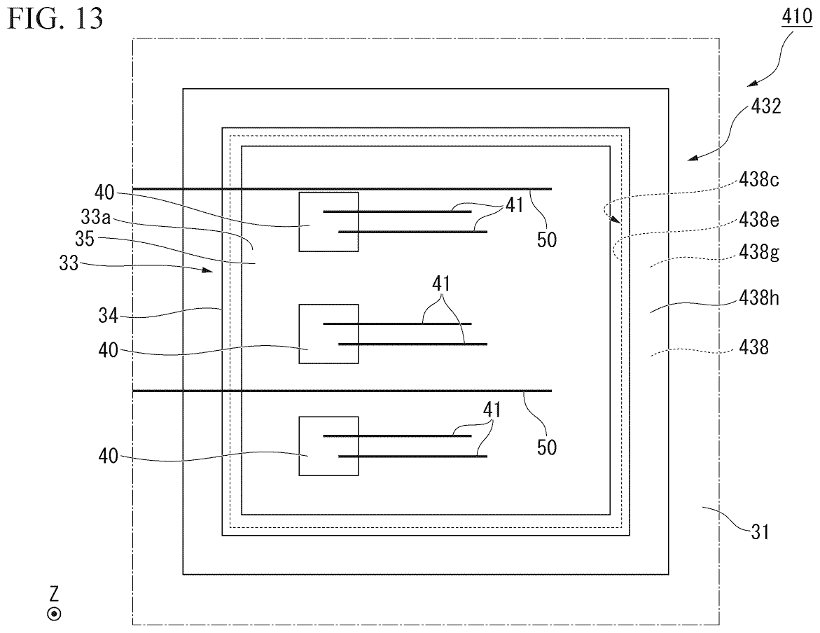

The recessed portion 438c is a hole recessed from the front surface 438a of the heat transfer member 438, that is, a surface facing the first side (positive Z side) to the second side (negative Z side). Namely, the recessed portion 438c is provided on the front surface 438a of the heat transfer member 438. As shown in FIG. 13, the recessed portion 438c is a hole substantially having a rectangular shape when viewed in the vertical direction. As shown in FIG. 12, the recessed portion 438c has a first inward side surface 438d and a second inward side surface 438e.

The first inward side surface 438d is a surface, of the inward side surfaces of the recessed portion 438c, facing the first side (positive Z side). The circuit board 33 is joined to the first inward side surface 438d with the first joint layer 37 therebetween. The second surface 33b of the circuit board 33 is disposed inside the recessed portion 438c. A part of the conductor portion 36 on the downward side is disposed inside the recessed portion 438c. As described above, the first joint layer 37 is a sintered body formed by pressureless sintering.

The second inward side surface 438e is a surface, of the inward side surfaces of the recessed portion 438c, facing a direction orthogonal to the vertical direction. The second inward side surface 438e surrounds the conductor portion 36. The second inward side surface 438e faces the conductor portion 36 in a direction orthogonal to the vertical direction.

The circumferential edge portion 438g is a part on the front surface 438a of the heat transfer member 438, that is, a surface facing the first side (positive Z side) surrounding the recessed portion 438c when viewed from the first side. As shown in FIG. 13, an outer edge of the circumferential edge portion 438g surrounds the outer edge of the circuit board 33. In addition, as shown in FIG. 12, in the vertical direction, the circumferential edge portion 438g is positioned on the first side of the second surface 33b. For this reason, the creepage distance between the circuit portion 35 and the circumferential edge portion 438g is shorter than the creepage distance between the circuit portion 35 and the conductor portion 36.

The insulating layer 438h is provided in the circumferential edge portion 438g. The insulating layer 438h has insulating properties. In the present embodiment, for example, the insulating layer 438h is constituted using a resin having insulating properties, such as polyimide (PI) or polytetrafluoroethylene (PTFE). Other constitutions and the like of the heat transfer member 438 are the same as the constitutions and the like of the heat transfer member 338 of the third embodiment described above. Other constitutions and the like of the semiconductor device 410 are the same as other constitutions and the like of the semiconductor device 310 of the third embodiment described above.

According to the present embodiment, the recessed portion 438c recessed to the second side (negative Z side) is provided on the front surface 438a of the heat transfer member 438, that is, a surface facing the first side (positive Z side), and the second surface 33b of the circuit board 33 is disposed inside the recessed portion 438c. When the position of the circuit board 33 with respect to the heat transfer member 438 significantly deviates in a direction orthogonal to the vertical direction, there is concern that the chip 40 and the wire 41 interfere with the terminal portion 50. In contrast, in the present embodiment, a part of the conductor portion 36 of the circuit board 33 on the downward side is disposed inside the recessed portion 438c. For this reason, the position of the circuit board 33 with respect to the heat transfer member 438 in a direction orthogonal to the vertical direction can be regulated by the second inward side surface 438e. Therefore, since significant positional deviation of the circuit board 33 with respect to the heat transfer member 438 in a direction orthogonal to the vertical direction can be curbed, interference of the chip 40 and the wire 41 with the terminal portion 50 can be curbed. Thus, operational stability of the semiconductor device 410 can be improved.

In addition, in the present embodiment, in the second joining step S02, the first joint layer 37 is formed by pressureless sintering. Therefore, in the second joining step S02, since a force of pressing the circuit board 33 against the heat transfer member 38 is not applied to the circuit board 33, the position of the circuit board 33 with respect to the heat transfer member 38 is likely to significantly deviate in a direction orthogonal to the vertical direction. In contrast, in the present embodiment, as described above, the position of the circuit board 33 with respect to the heat transfer member 438 in a direction orthogonal to the vertical direction can be regulated by the second inward side surface 438e. For this reason, significant deviation of the position of the circuit board 33 with respect to the heat transfer member 38 in a direction orthogonal to the vertical direction can be curbed. Therefore, even if the first joint layer 37 is formed by pressureless sintering, interference of the chip 40 and the wire 41 with the terminal portion 50 can be curbed. Thus, operational stability of the semiconductor device 410 can be improved.

According to the present embodiment, the insulating layer 438h having insulating properties is provided in the circumferential edge portion 438g on a surface of the heat transfer member 438 facing the first side (positive Z side) surrounding the recessed portion 438c when viewed from the first side. Thus, as described above, even in the case where the creepage distance between the circuit portion 35 and the circumferential edge portion 438g is short, the circuit portion 35 and the circumferential edge portion 438g can be insulated from each other by the insulating layer 438h. Therefore, operational stability of the semiconductor device 410 can be more favorably improved.

According to at least one of the embodiments described above, it is possible to provide a semiconductor device in which an excessive rise in the temperature of a chip can be curbed by having the first joint layer and the second joint layer which are sintered bodies.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a circuit board having a first surface facing a first side, and a second surface facing a second side on a side opposite to the first side;
a chip mounted on the first surface;
a heat transfer member joined to the second surface with a first joint layer therebetween; and
a heat dissipation member joined to a surface of the heat transfer member facing the second side with a second joint layer therebetween,
wherein each of the first joint layer and the second joint layer is a sintered body.

2. The semiconductor device according to claim 1,
wherein an outer surface of the heat dissipation member is covered by a nickel protective film, and
the second joint layer is a silver sintered body.

3. The semiconductor device according to claim 1,
wherein the heat transfer member is made of copper, and
the first joint layer is a copper sintered body.

4. The semiconductor device according to claim 3,
wherein the circuit board has an insulating substrate having insulating properties, and a conductor portion formed on a surface of the insulating substrate facing the second side,
the conductor portion is made of copper, and
the conductor portion and the heat transfer member are joined to each other with the first joint layer therebetween.

5. The semiconductor device according to claim 1,
wherein the heat transfer member is joined to a conductor portion formed on the circuit board with the first joint layer therebetween, and
when viewed from the first side, an outer edge of the heat transfer member overlaps an outer edge of the conductor portion, or surrounds the outer edge of the conductor portion.

6. The semiconductor device according to claim 1,
wherein when viewed from the first side, the outer edge of the heat transfer member surrounds an outer edge of the circuit board.

7. The semiconductor device according to claim 1,
wherein a recessed portion recessed to the second side is provided on a surface of the heat transfer member facing the first side, and
the second surface of the circuit board is disposed inside the recessed portion.

8. The semiconductor device according to claim 7,
wherein the heat transfer member has a circumferential edge portion on the surface facing the first side,
when viewed from the first side, the circumferential edge portion surrounds the recessed portion, and
an insulating layer having insulating properties is formed on the circumferential edge portion.

9. The semiconductor device according to claim 1 further comprising:
a case accommodating each of the circuit board and the heat transfer member therein;
a terminal portion held by the case and connected to the circuit board;
a wire connecting the chip and the circuit board to each other; and
a sealing material covering each of the circuit board, the chip, and the wire and having insulating properties.

10. A method for manufacturing a semiconductor device including a circuit board having a first surface facing a first side, and a second surface facing a second side on a side opposite to the first side,
a chip mounted on the first surface,
a heat transfer member joined to the second surface with a first joint layer therebetween, and
a heat dissipation member joined to a surface of the heat transfer member facing the second side with a second joint layer therebetween,
the method comprising:
a first joining step of forming the second joint layer by pressure sintering and joining the heat transfer member and the heat dissipation member to each other with the second joint layer therebetween; and
a second joining step of forming the first joint layer by pressureless sintering and joining the circuit board having the chip mounted thereon and the heat transfer member to each other with the first joint layer therebetween.

11. The method for manufacturing a semiconductor device according to claim 10,
wherein the heat transfer member is made of copper,
the circuit board has an insulating substrate having insulating properties, and a copper conductor portion formed on a surface of the insulating substrate facing the second side,
the first joint layer is a copper sintered body, and
the conductor portion and the heat transfer member are joined to each other with the first joint layer therebetween.

12. A method for manufacturing a semiconductor device including a circuit board having a first surface facing a first side, and a second surface facing a second side on a side opposite to the first side,
a chip mounted on the first surface,
a heat transfer member joined to the second surface with a first joint layer therebetween, and
a heat dissipation member joined to a surface of the heat transfer member facing the second side with a second joint layer therebetween,
the method comprising:
a first joining step of forming the second joint layer by pressure sintering and joining the heat transfer member and the heat dissipation member to each other with the second joint layer therebetween;
a second joining step of forming the first joint layer by pressure sintering and joining the circuit board and the heat transfer member to each other with the first joint layer therebetween; and
a mounting step of mounting the chip on the first surface after the second joining step.
